(19) United States
(12) Patent Application Publication
(10) Pub. No.: US 2022/0277929 A1
(43) Pub. Date: Sep. 1, 2022

(54) SINGLE-TURN AND LAMINATED-WALL INDUCTIVELY COUPLED PLASMA SOURCES

(71) Applicant: Advanced Energy Industries, Inc., Denver, CO (US)

(72) Inventors: Scott Polak, Fort Collins, CO (US); Yong Jiun Lee, Singapore (SG); Andrew Shabalin, Fort Collins, CO (US); David W. Madsen, Fort Collins, CO (US)

(21) Appl. No.: 17/749,394

(22) Filed: May 20, 2022

Related U.S. Application Data
(63) Continuation of application No. 16/292,448, filed on Mar. 5, 2019.

(51) Int. Cl. H01J 37/32

(52) U.S. Cl. CPC H01J 37/321; H01J 37/32357; H01J 37/32651; H01J 2237/026

(57) ABSTRACT

This disclosure describes systems, methods, and apparatus for making and using a single-turn coil on a remote plasma source to reduce capacitive coupling between the coil and a plasma, and/or a laminated chamber wall including at least one conductive layer that reduces capacitive coupling between the coil and the plasma. Where a laminated chamber wall is used, the coil can either be a single or multi-turn coil. Additive processes can be used to fuse or bond the conductive layer(s) to lower layers (e.g., dielectric layers) as well as to fuse or bond a final layer (e.g., dielectric) to an outermost conductive layer. Further, a method is disclosed wherein a conductive layer within the lamination is biased during plasma ignition and then the bias is reduced after ignition.

### CLAIM OF PRIORITY UNDER 35 U.S.C. § 120

The present Application for Patent is a Continuation of patent application Ser. No. 16/292,448 entitled “SINGLE-TURN AND LAMINATED-WALL INDUCTIVELY COUPLED PLASMA SOURCES” filed Mar. 5, 2019, pending, and assigned to the assignee hereof and hereby expressly incorporated by reference herein.

### FIELD OF THE DISCLOSURE

The present disclosure relates generally to remote plasma sources. In particular, but not by way of limitation, the present disclosure relates to systems, methods and apparatuses for reducing capacitive coupling between a remote plasma source coil and the plasma within the chamber.

### DESCRIPTION OF RELATED ART

FIG. 5 illustrates a typical cylindrical remote plasma source chamber. The chamber includes a dielectric chamber wall surrounded by a helical coil. The coil is biased with AC power to inductively couple power into a plasma within the chamber. The plasma establishes a positive, DC potential as it self-insulates from the chamber wall. The voltage of the helical coil is proportional to the number of turns, and thus portions of a multi-turn coil develop a significant potential difference from nearby components, both adjacent turns of the coil as well as electrically-grounded components of the enclosure or chassis. The potential difference generates an electric field across the chamber wall. As ions diffuse radially near the boundary of the plasma, their trajectory is increasingly captured by the electric field and accelerated through the plasma sheath toward the wall. These accelerated ions collide with and sputter (erode) the chamber wall, especially near an end of the coil and flanges of the chamber. This unintentional capacitive coupling is a common problem in inductively coupled plasma sources and leads to premature deterioration of the chamber wall. This same issue is seen in remote plasma sources using a planar-type coil.

While other attempts to mitigate this chamber degradation have been made (e.g., U.S. Pat. No. 9,818,584), their solutions tend to be suboptimal. For instance, U.S. Pat. No. 9,818,584 suggests that Faraday shields arranged between the coil and the chamber wall 102 with air between all three of these components are undesirable since they can cause “a high voltage discharge which could damage the source” and could lead to arcing in the region between the shield and the chamber. This reference also notes that placing “Faraday shield between the plasma chamber and the antenna also inevitably leads to the antenna being placed further away from the plasma vessel, which can cause complications including arcing from the antenna to the shield and from the shield to the plasma. Furthermore, Faraday shields may have sharp edges which cause additional high voltage management concerns,” and the “Faraday shield can complicate the cooling methods.”

As another example, U.S. Pat. No. 6,924,455 states “Faraday shields have been used in inductively coupled plasma sources to shield the high electrostatic fields. However, because of the relatively weak coupling of the drive coil currents to the plasma, large eddy currents form in the shields resulting in substantial power dissipation. The cost, complexity, and reduced power efficiency make the use of Faraday shields unattractive.”

U.S. Pat. No. 8,692,217 also teaches away from use of a split Faraday shield for two main reasons: (1) a degree of capacitive coupling is allegedly required to ignite the plasma, and use of a split Faraday shield usually requires another external power source (e.g., a Tesla coil) to ignite the plasma; and (2) split Faraday shields typically result in some energy loss due to Eddy currents induced in the shield, and thus a balanced antenna approach is superior.

Other prior art discussions of shielding include, Electrostatically-Shielded Inductively-Coupled RF Plasma Sources. L. Johnson, Wayne. (1996). 100-148. 10.1016/B978-081551377-3.50005-0. Other examples of a Faraday shield arranged between a chamber wall and an inductive plasma source can be seen in Faraday shielding of one-turn planar ICP antennas. Ganachev, et al. 2016. IEEE. Progress in Electromagnetic Research Symposium (PIERS) and A new inductively coupled plasma source design with improved azimuthal symmetry control. Marwan H Khater and Lawrence J Overzet. Plasma Sources Science and Technology, Volume 9, Number 4.

Other prior art attempts place the Faraday shield within the chamber (e.g., Schematic-of-ICP-ion-source-C-1-and-C-2-are-the-impedance-matching-capacitors-V-ext_fig3_46276097).

From the prior art it is clear that adding layers to a chamber wall increases cost and complexity and moves the coil further from the plasma, which decreases thermal evacuation and reduces inductive coupling with the plasma. Thus, the art appreciates that thinner chamber walls are preferable.

### SUMMARY OF THE DISCLOSURE

The following presents a simplified summary relating to one or more aspects and/or embodiments disclosed herein. As such, the following summary should not be considered an extensive overview relating to all contemplated aspects and/or embodiments, nor should the following summary be regarded to identify key or critical elements relating to all contemplated aspects and/or embodiments or to delineate the scope associated with any particular aspect and/or embodiment. Accordingly, the following summary has the sole purpose to present certain concepts relating to one or more aspects and/or embodiments relating to the mechanisms disclosed herein in a simplified form to precede the detailed description presented below.

Some embodiments of the disclosure may be characterized as a remote plasma source chamber with extended lifetime configured for coupling to a processing chamber. The remote plasma source chamber can include a cylindrical chamber having an inner portion, an outer portion, and a conductive middle portion. The inner and outer portions can include a dielectric and the conductive middle portion between the inner and outer portions can define one or more magnetic-field-passage windows. The inner and outer portions can encase the conductive middle portion and preclude exposure of the middle portion to plasma when the remote plasma source chamber is in operation. This is most applicable when a vacuum seal between the remote source and the processing chamber is made at an inner surface of the inner portion. However, where the vacuum seal is made at an outer surface of the outer portion, then encasement of the ends of the middle portion is not needed. A conductive coil can be arranged outside but in contact with the cylindrical chamber, and can include a first end and a second end, the first end configured for coupling to a high voltage node of an alternating current power supply, the second end configured for coupling to a low voltage or ground node of the alternating current power supply.

Other embodiments of the disclosure may also be characterized as a method for manufacturing a remote plasma source chamber having extended lifetime due to reduced capacitive sputtering of walls of the chamber, the chamber configured for coupling to and providing a plasma to a processing chamber. The method can include forming a cylindrical chamber, where this process can include providing a cylindrical inner portion formed with a dielectric. This process can then include depositing a conductive layer onto an outer surface of the inner portion, where the conductive layer includes one or more windows exposing the dielectric through the conductive layer. This process can further include depositing a first dielectric layer over the exposed inner portion and the conductive layer. This process can yet further include arranging a conductive coil outside but in contact with the cylindrical chamber, the conductive coil including a first end and a second end, the first end configured for coupling to a high voltage node of an alternating current power supply, the second end configured for coupling to a low voltage or ground node of the alternating current power supply.

Other embodiments of the disclosure can be characterized as a system for an inductively-coupled remote plasma source having a single-turn coil (or a double or triple-turn coil) wrapped around either a traditional dielectric chamber wall or a laminated chamber wall including at least one conductive layer sandwiched between dielectric layers. The single-turn coil and chamber can be immersed in a curable polymer having ceramic particles therein, or some other curable thermal transfer medium. The single-turn coil can be operated in an inductive regime during maintenance of the plasma and may be biased to a higher ignition voltage for a short period of time to ignite the plasma. Alternatively, or in parallel, the optional conductive layer(s) within the chamber wall can be biased to a high voltage to enhance capacitive coupling to the plasma and ignite or help to ignite the plasma.

Other embodiments of the disclosure can be characterized as a remote plasma source system including a cylindrical chamber having: an inner portion comprising a dielectric; an outer portion comprising a dielectric; a conductive middle portion between the inner and outer portion defining one or more magnetic-field-passage windows. At the same time, the inner and outer portions can encase the middle portion and preclude exposure of the middle portion to plasma when the remote plasma source chamber is in operation. Lastly, a conductive coil can be arranged outside but in contact with the cylindrical chamber. The conductive coil can include a first end and a second end, where the first end can be configured for coupling to a high voltage node of an alternating current power supply, and the second end can be configured for coupling to a low voltage or ground node of the alternating current power supply. The cylindrical chamber can further include one or more gas inlets, and one or more plasma or chemical species outlets. The cylindrical chamber can include power connections that can interface between a power source and the conductive coil. In some embodiments, the system can be a downstream system rather than an upstream source.

In other embodiments of the disclosure, the remote plasma source system noted in the preceding paragraph can be part of a plasma processing system. Said system can include the aforementioned remote plasma source system coupled to a processing chamber. The processing chamber can include a substrate holder and a bias for the substrate holder. The processing chamber can include a gas/plasma exit conduit and a pump configured to remove gas/plasma via the exit conduit.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1a shows a plasma processing system with an upstream inductively-coupled remote plasma source having a single-turn coil around the cylindrical chamber.

FIG. 1B shows a plasma processing system with an upstream inductively-coupled remote plasma source having a multi-turn coil around the cylindrical chamber.

FIG. 2a shows a plasma processing system with a downstream inductively-coupled remote plasma source having a single-turn coil around the cylindrical chamber.

FIG. 2b shows a plasma processing system with a downstream inductively-coupled remote plasma source having a single-turn coil around the cylindrical chamber.

FIG. 3a shows a first embodiment of a length of a single-turn coil.

FIG. 3b shows a second embodiment of a length of a single-turn coil.

FIG. 3c shows a variation of the single-turn coil split into multiple, identically-biased, portions.

FIG. 4a shows a first state of the bias circuitry shown in FIG. 3c.

FIG. 4b shows a second state of the bias circuitry shown in FIG. 3c.

FIG. 5 illustrates a typical cylindrical remote plasma source chamber.

FIG. 6 illustrates a cross-sectional view of the remote plasma sources shown in FIG. 1.

FIG. 7 illustrates the cross sections of FIG. 6 but with two conductive layers, and a dielectric layer arranged between these.

FIG. 8 shows two different magnetic-field-passage window patterns.

FIG. 9 shows two different magnetic-field-passage window patterns where one layer is primary for shielding and one is primary for heat spreading.

FIG. 10 shows two different magnetic-field-passage window patterns where one layer is primary for shielding and one is primary for heat spreading.

FIG. 11 shows two different magnetic-field-passage window patterns where one layer is primary for shielding and one is primary for heat spreading.

FIG. 12 shows two isolated shielding regions each with a distinct bias.

FIG. 13 illustrates a cross section of a remote plasma source having an inner portion, a first conductive layer, a dielectric layer, a second conductive layer, an outer portion, and a single-turn or multi-turn coil in contact with and surrounding the outer portion.

FIG. 14 shows a cross section of a remote plasma source having a multi-turn coil and a laminated chamber wall including a conductive layer between dielectric layers.

FIG. 15 illustrates a method of operating a remote plasma source.

FIG. 16 illustrates a method of fabricating a laminated remote plasma source chamber with a single or multi-turn coil.

FIG. 17 illustrates a method of fabricating a laminated remote plasma source with a single or multi-turn coil and at least two conductive layers.

FIG. 18 illustrates a method of applying a curable thermal transport medium to a laminated remote plasma source chamber with either a single or multi-turn coil.

FIG. 19 illustrates another method of fabricating a remote plasma source chamber with a single-turn coil formed via an additive process.

FIG. 20 illustrates a housing into which a remote plasma source can be placed in preparation for pouring of a thermal transport medium.

FIG. 21 illustrates a cross section of the housing in FIG. 20, but with the addition of optional chimney tubes.

FIG. 22 shows a block diagram depicting physical components that may be utilized to realize a device for operating or manufacturing the remote plasma sources herein disclosed according to an exemplary embodiment.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Preliminary note: the flowcharts and block diagrams in the following Figures illustrate the architecture, functionality, and operation of possible implementations of systems, methods and computer program products according to various embodiments of the present invention. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

For the purposes of this disclosure, an additive process includes any method that adds one or more layers of a conductor or dielectric to a substrate or preceding layer. Additive processes can include various coating processes including, but not limited to: chemical vapor deposition, physical vapor deposition, sputtering, electroplating, kinetic metallization, powder coating, and thermal spraying (e.g., plasma spraying, detonation spraying, wire arc spraying, flame spraying, high velocity oxygen fuel spraying, high velocity air fuel spraying, cold spraying, warm spraying, etc.). Additive layers can span thicknesses from sub-micron to thousands of microns.

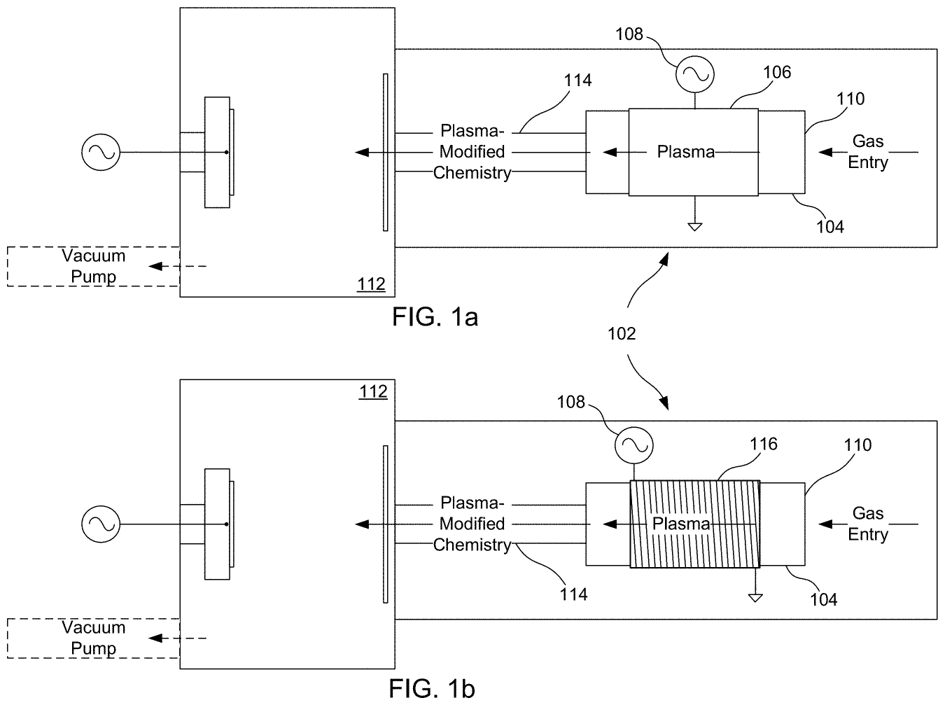

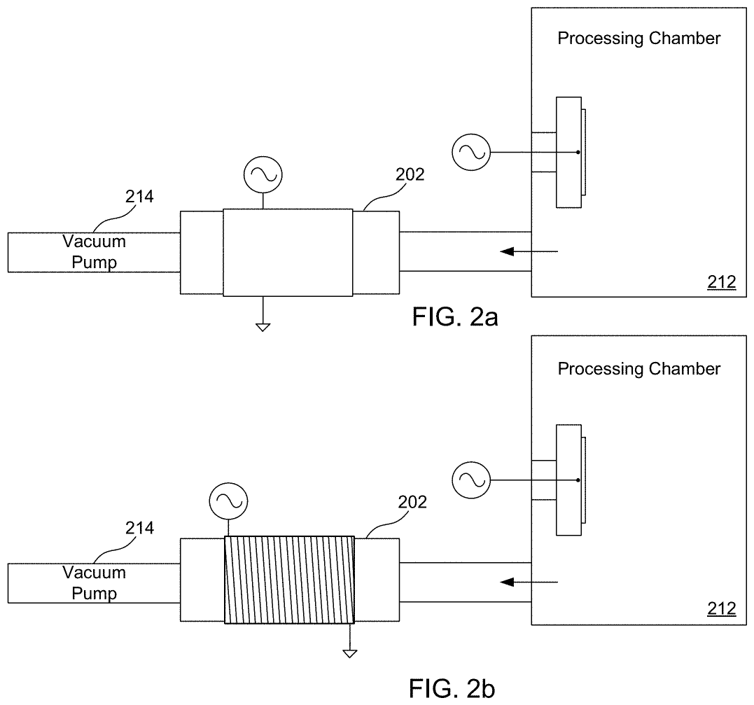

Given the prior art's antagonism toward Faraday shields arranged external to the chamber, this disclosure focuses on three primary embodiments of a remote plasma source with a Faraday shield laminated into the chamber wall. These three embodiments use an additive manufacturing method or fusing method to molecularly couple layers to each other such that thermal transport between the chamber and the liquid-cooled coils is not inhibited. These three embodiments include the following: (1) one using a laminated chamber wall and a helical coil surrounding the chamber wall; (2) one using a laminated chamber wall and a single-turn coil surrounding the chamber wall; and (3) one using a sing-turn coil surrounding the chamber wall. FIGS. 1a, 1b, 2a, and 2b show system-level views of these different embodiments being implemented as remote plasma sources upstream of the processing chamber (FIGS. 1a and 1b) as well as downstream of the processing chamber (see FIGS. 2a and 2b). In FIG. 1a the remote plasma source 102 includes a cylindrical chamber 104, having a single-turn coil 106 wrapped around a majority of a circumference of and in contact with an outside surface of the cylindrical chamber 104. The single-turn coil 106 can wrap around roughly 98% of a circumference of the cylindrical chamber 104, with a gap between two ends of the coil 106, such that each end can be biased to a different potential. In other embodiments, the single-turn coil can wrap around 1−t/(ID+2*t), or 1−t/OD, where ID is the inner diameter of the cylindrical chamber 104 and t is the chamber wall thickness, and OD is the outer diameter of the chamber wall (e.g., OD=ID+2*t). Said another way, the single-turn coil 106 should wrap around the cylindrical chamber 104 so that a gap between the ends is no more than a thickness of the single-turn coil 106. This preferred range of thickness is intended to avoid detrimental thermal gradients through the radial thickness of the single-turn coil 106. A power supply 108 can be coupled to these two ends and provide AC power to the single-turn coil 106, such that alternating current passing through the coil, and around the cylindrical chamber 104 generates and/or maintains a plasma within the cylindrical chamber 104. The cylindrical chamber 104 can include a gas inlet 110, where one or more gases can be provisioned to the cylindrical chamber 104, modified by the plasma within the cylindrical chamber 104 to form a plasma-modified chemistry (e.g., by generation of free radicals), and then passed into a processing chamber 112. An optional attenuation region 114 can be arranged between the cylindrical chamber 104 and the processing chamber 112 to allow passage of the plasma-modified chemistry while also causing attenuation of any electromagnetic fields generated in in the cylindrical chamber 104. The cylindrical chamber 104 can be formed from a dielectric, or a lamination comprising: at least an inner portion (e.g., dielectric), a conductive middle portion (e.g., Ag, Au, Cu, MoMn), and an outer portion (e.g., dielectric). In some embodiments, further conductive portions can be added as long as each conductive portion is separated from adjacent conductive portions by a dielectric portion, and a further dielectric portion is included as the final outer layer.

FIG. 1B shows the same system but with a multi-turn coil 116 around the cylindrical chamber 104. In this embodiment, the multi-turn coil 116 can be coupled to a power supply 108 at both ends of the multi-turn coil 116. In both embodiments, the coil can extend along at least 25% the length of the cylindrical chamber 104 and up to 100% the length of the cylindrical chamber 104 or along at least 75% of the length of the cylindrical chamber 104 and up to 90% the length of the cylindrical chamber.

FIG. 2 illustrates embodiments of a remote plasma source being used in a downstream application, for instance where the remote plasma chamber 202 is arranged between the processing chamber 212 and a vacuum pump 214, to generate a plasma to modify the chemistry of the gases in processing chamber 212 egress (e.g. the abatement of PFC gases with high global warming potentials). More specifically, an inductively coupled remote plasma source can be arranged downstream of the plasma chamber 202, where water vapor is used as a catalyst to “scrub” exhaust gases such as SFx and CFx. This results in a modified byproduct chemistry that are nonvolatile and safer for release into the atmosphere.

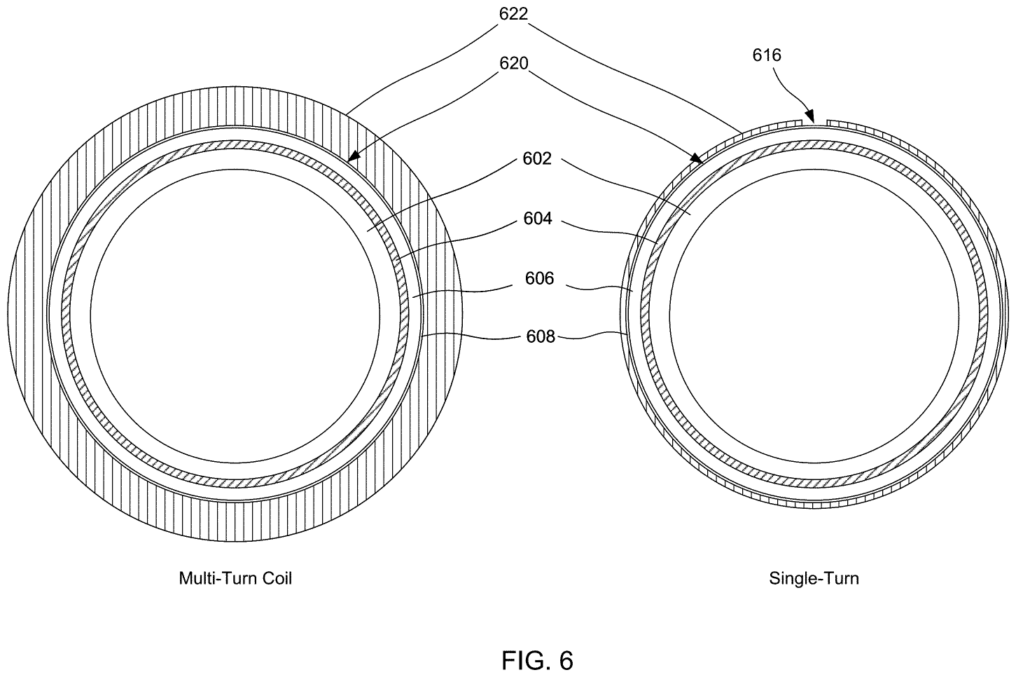

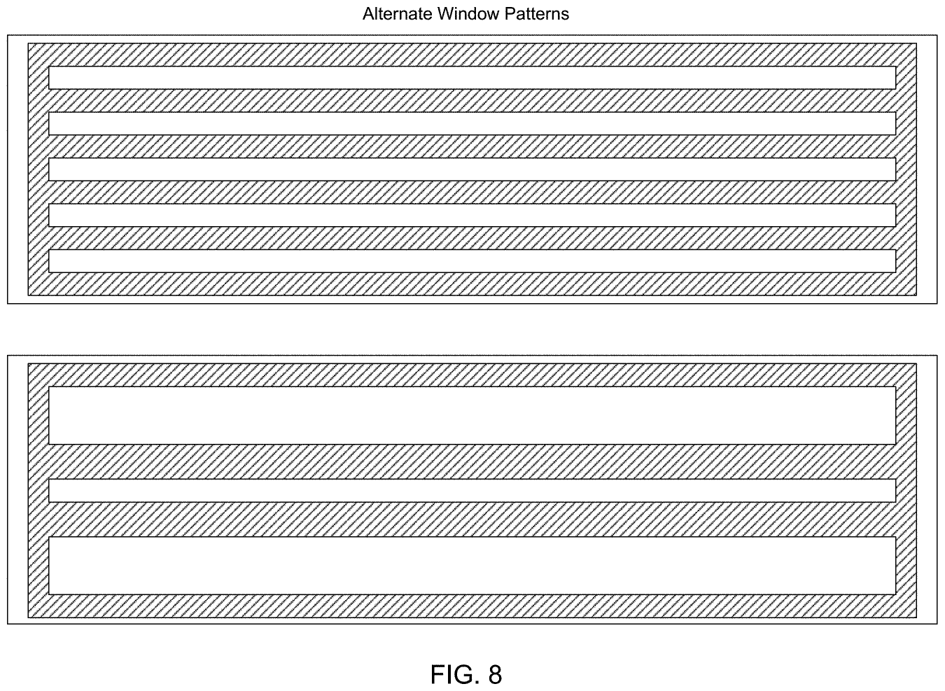

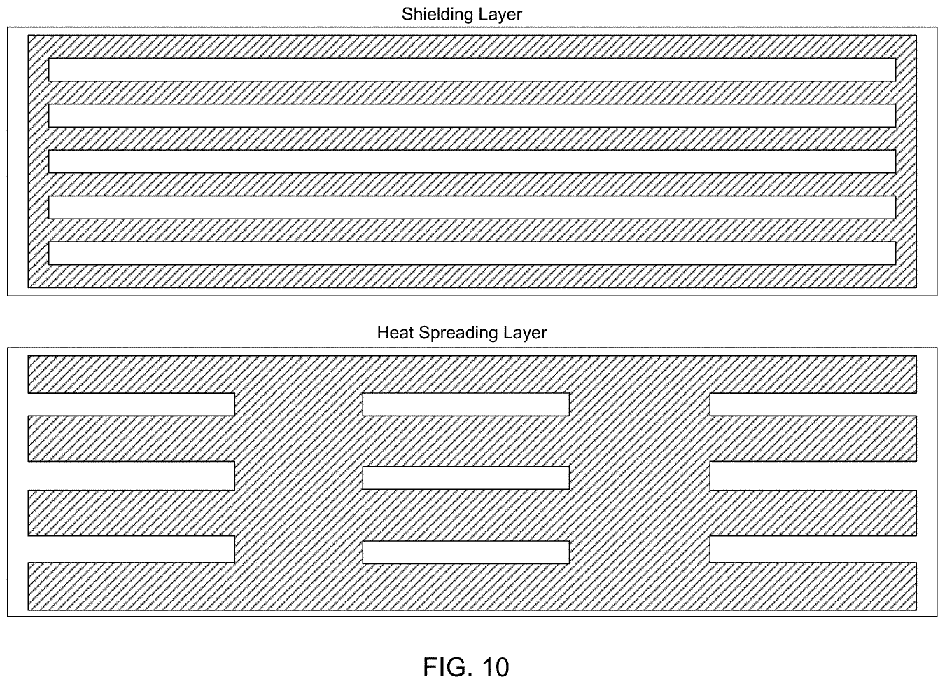

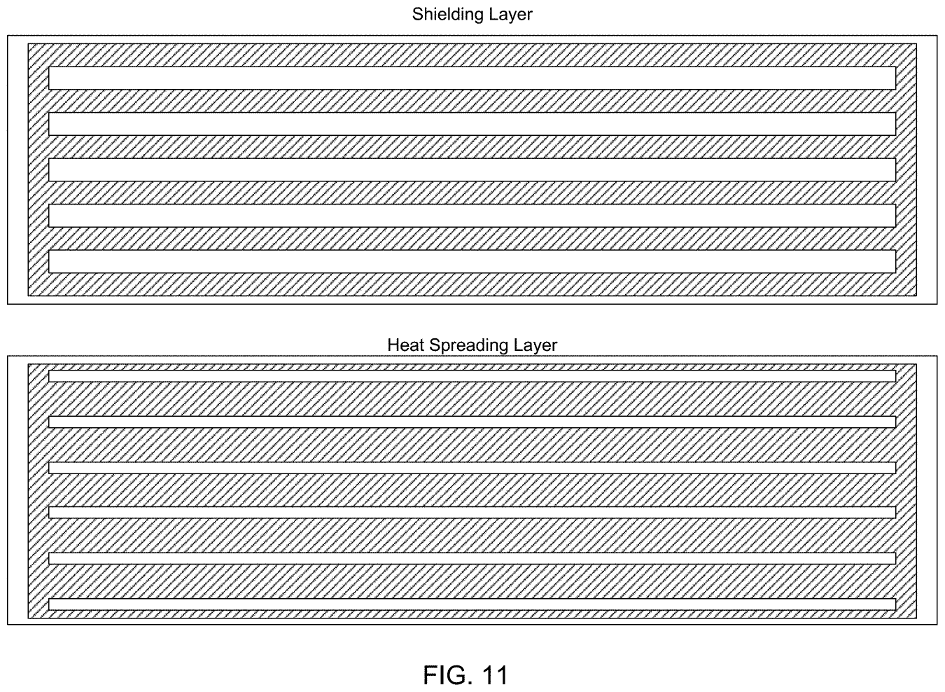

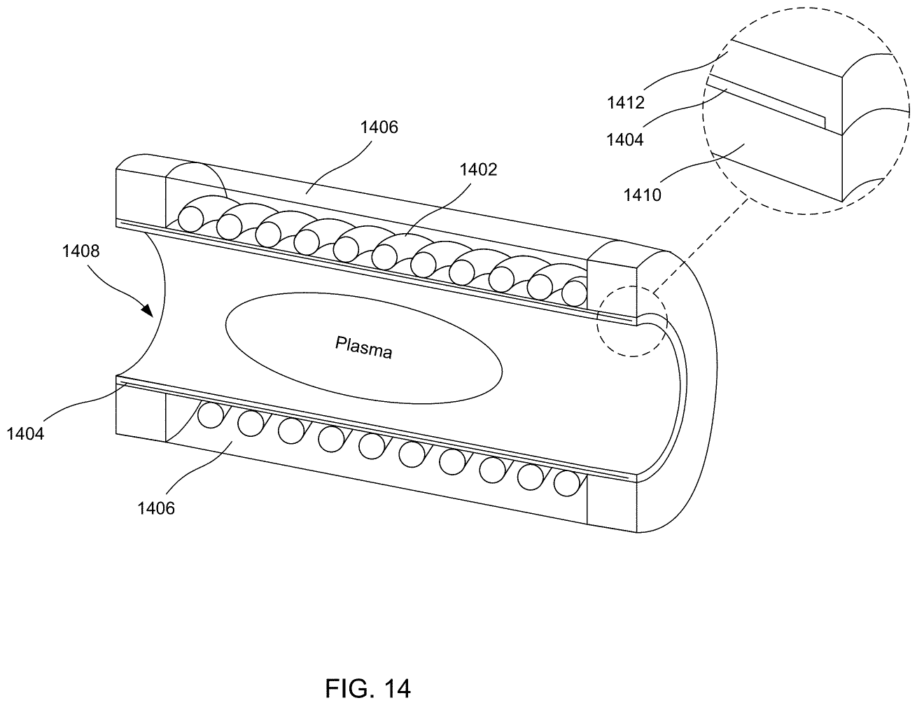

FIG. 6 illustrates a cross-sectional view of the remote plasma sources 102 shown in FIG. 1. On the left is the embodiment of FIG. 1B where a multi-turn coil is used, and on the right is the embodiment of FIG. 1a where a single-turn coil is used. In both embodiments, the cross section can be the same, except with regards to the coil, where the single-turn variant includes a gap 616 between ends of the single-turn coil. Where a single-turn coil is used, the cross section of the coil can include a width (longitudinally measured along a length of the chamber) to thickness ratio of 0.5 to 4.0. The remote plasma source can include a cylindrical chamber 620 including an inner portion 602 comprising a dielectric, an outer portion 606 comprising a dielectric or insulator, and a conductive middle portion 604 between the inner and outer portions 602, 606. The conductive middle portion 604 can define one or more magnetic-field-passage windows, for instance as seen in FIGS. 8-12. In particular, FIG. 8 shows two different magnetic-field-passage window patterns, though many others can also be implemented. The inner and outer portions 602, 606 can encase the conductive middle portion 604 and preclude exposure of the middle portion 604 to plasma when the remote plasma source is in operation. For instance, the close up view in FIG. 14 shows how the inner and outer portions 602, 606 can be arranged to enclose the conductive middle portion 604 by meeting/bonding at ends of the cylindrical chamber 620.

The remote plasma source can also include a conductive coil 622 arranged outside but in contact with the cylindrical chamber 620. Adding thickness to the cylindrical chamber 620 diminishes thermal transport to the coil 622, and thus innovations are needed to enhance thermal transport. Accordingly, a thermal transfer medium 608 can be arranged between the conductive coil 622 and the cylindrical chamber 620 to remove any air gaps between the two components. The thermal transfer medium 608 can include a polymer with its thermal conductivity enhanced by including electrically conductive or dielectric, thermally-conductive particles such as a silicone with ceramic particles distributed therein. For instance, the thermal transport medium 608 can be 2-part silicone-based elastomer with ceramic particles included to enhance thermal conductivity. The thermal transport medium can be a dielectric so that its contact with the coil 622 does not short adjacent coils. In another example where lower heat fluxes are at play, a non-modified polymer may be used, such as silicone-based gels or adhesives, urethane-based adhesives, etc.

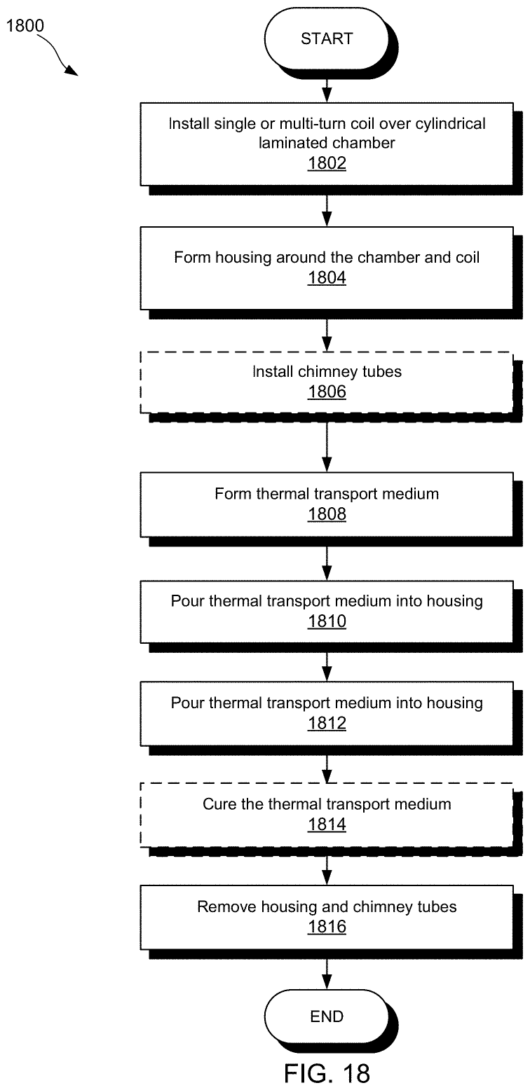

In some embodiments, the thermal transfer medium 608 can also surround sides of the conductive coil 622 thereby increasing the coil 622 surface area through which thermal transport from the cylindrical chamber 620 can take place (e.g., see FIG. 18). For instance, FIG. 14 shows an embodiment where a thermal transfer medium 1406 surrounds the conductive coil 1402 and thereby increases the surface area of the conductive coil 1402 that can accept heat transfer from the cylindrical chamber 1408. The thermal transport medium 608 can be applied in an uncured state such that it flows around the conductive coil 622 and fills any air gaps between the cylindrical chamber 620 and the coil 622. The thermal transport medium 608 can be flowed into a chamber encasing the cylindrical chamber 620 as well as the conductive coil 622 and then cured such that the cured thermal transport medium 608 can enclose at least 60% of a surface of the conductive coil 622.

The conductive coil 622 can include first and second ends, where the first end is configured for coupling to a first node of an alternating current power supply, and where the second end is configured for coupling to a second node of the alternating current power supply (e.g., see FIGS. 1-3).

The conductive middle portion 604 can be formed from MoMn, silver, copper, aluminum, or any other conductor having a high thermal conductivity. MoMn may be preferred over other conductors since it is less likely to migrate to an inside of the cylindrical chamber during lamination and consequently contaminate the plasma-exposed surfaces of the chamber.

The conductive middle portion 604 can be formed by any additive manufacturing process, such as sputtering or spraying or any method of fusing two components, such as, but not limited to, brazing. Preferably, the conductive middle portion 604 is between 10-40 μm thick if the middle portion 604 is to be used for electromagnetic purposes only (i.e. shielding or promoting capacitively coupling to the plasma). Alternatively, if the middle portion 604 is also to be used for heat spreading, then the thickness of the middle portion should be sufficiently thick such that the thermal resistance through 604 in the axial direction is less than or equal to the thermal resistance of an equivalent volume (thickness) of the dielectric chamber wall in the radial direction.

The inner portion 602 can be formed from a dielectric, such as Al₂O₃ or Al₂O₃Y₂O₃. For instance, the inner portion 602 can be a dielectric that is both electrically insulating and thermally conductive (e.g., Al₂O₃).

The outer portion 606 can be formed from a dielectric, such as Al₂O₃ or Al₂O₃Y₂O₃. For instance, the outer portion 606 can be a dielectric that is both electrically insulating and thermally conductive. The outer portion 606 can be formed by any additive manufacturing method sputtering or spraying or any method of fusing two components, such as brazing. In an embodiment, flame spraying can be used to apply a ceramic as the outer portion 606. The outer portion 606 can have a thickness of between 1-100 μm.

Because of the importance of thermal transport to the coil in an inductively-coupled plasma chamber, the inventors first attempted to form a series of layers with thermal grease between the layers. However, the thermal grease provided more thermal resistance than was acceptable. Instead, the inventors discovered that a lamination, where layers were molecularly bonded or fused to each other (e.g., spraying, deposition, additive processes, brazing) rather than separated by thermal grease, was the only way to achieve sufficient thermal transport to the coil.

In some cases the coil can be brazed to an outside of the laminated chamber, for instance via a brazing flux. However, thermal grease can be used for this one interface with acceptable results. In other embodiments, the single-turn or multi-turn coil can be fused to the cylindrical chamber 620 via metallization, metal thick-films or other metal coating processes. Where such fusing takes place, the thermal transport medium 608 can be forgone.

In some embodiments, the single-turn coil can comprise a thin conductive layer fused to an outer surface of the cylindrical chamber 620. This layer may be too thin to accommodate an internal fluid passage as is more typical in the multi-turn embodiments. As such, a cooling fluid pipe can be fused or otherwise bonded to an outside of this thin conductive layer to provide thermal cooling. Alternatively, a jacket or thin film of fluid, air-cooling, or other fluid impingement on the thin conductive layer can be used to accomplish thermal removal from the thin conductive layer. At the same time, without an internal liquid pathway, the thin conductive layer can be applied via additive manufacturing methods such as sputtering, spraying, deposition, etc. Electrical connections to the two ends of the thin conductive layer can be formed as one or more brazed or soldered power tap blocks, electrically conductive gaskets or springs, or flexible straps, to name just a few non-limiting examples.

The conductive middle portion can be formed as a floating element, or can be formed with an electrical connection for grounding, biasing, or both during different periods of operation of a plasma processing recipe. For instance, the conductive middle portion can be biased to a high voltage during plasma ignition to enhance capacitive coupling with the plasma, and then grounded during processing to act as a Faraday shield and thereby reduce capacitive coupling between the coil and the plasma. To enable this functionality, the conductive middle portion 604 can include an electrical connection for grounding, biasing, or both during different periods of operation of a plasma processing recipe. For instance, the electrical connection can enable the conductive middle portion 604 to be coupled to a power source that can ground the conductive middle portion 604 or apply a 0 V bias once ignition is complete. However, during plasma ignition, where capacitive coupling can enhance ignition of an inductively-coupled-plasma source, the power source can provide a bias that actually increases capacitive coupling between the conductive middle portion 604 and the plasma.

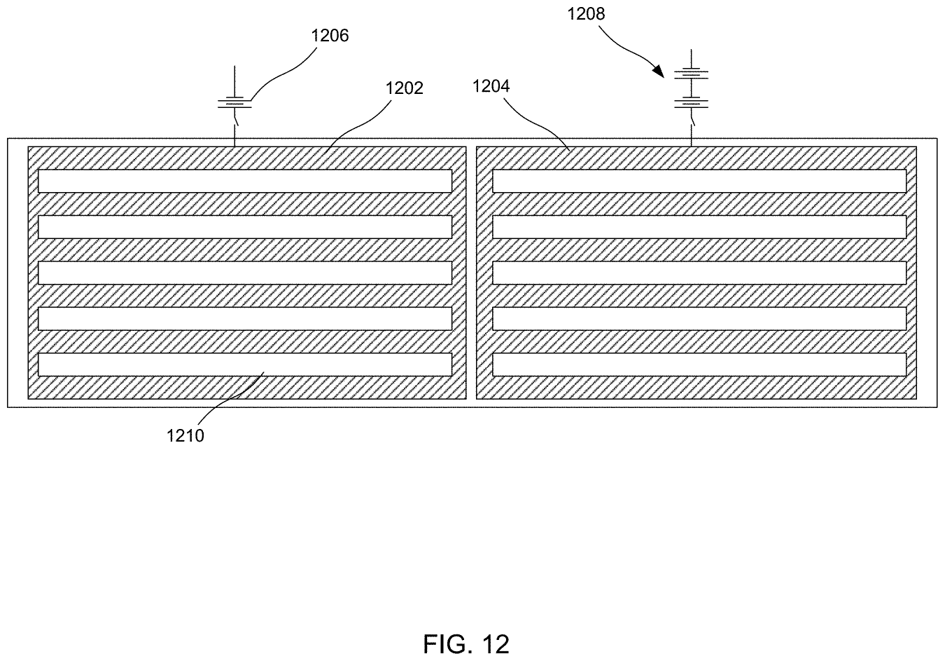

To this same end, the conductive middle portion can comprise multiple independent portions as seen, for instance, in FIG. 12. In this fashion, the multiple independent portions can be biased to different potentials at the same time. For instance, each of the two portions 1202, 1204 of the conductive middle portion 604 can be coupled to a distinct selectable bias 1206, 1208. FIG. 12 shows two isolated regions and two distinct biases, however, in other embodiments more than two isolated regions and/or more than two distinct biases could be implemented. Alternatively, the biases could be provided by a single power supply having circuitry enabling multiple independent outputs. Further, though the magnetic-field-passage windows 1210 are the same for the two regions 1202, 1204, in other embodiments, one or more of the regions 1202, 1204 could have a distinct window pattern.

Returning to FIG. 6, each of the inner, outer, and conductive middle portions 602, 604, 606 can have the same or distinct thicknesses. In one embodiment, the inner and outer portions 602, 606 are thicker than the conductive middle portion 604. In another embodiment, the inner portion 602 can be thicker than the outer portion 606, and the outer portion 606 can be thicker than the conductive middle portion 604. In another embodiment, the inner portion 602 can be thicker than the conductive middle portion 604, and the conductive middle portion 604 can be thicker than the outer portion 606.

The inner and outer portions 602, 606 can be bonded or fused to each other at ends of the cylindrical chamber 620 (see detail in FIG. 14) as well as through the magnetic-field-passage windows. This may be desirable where the vacuum seal is made at an outer surface of the outer portion 606. However, where the vacuum seal is made at the inner surface of the inner portion 602, then encasing the middle portion 604 at the ends is not necessary. In this way the inner and outer portions 602, 606 fully enclose the conductive middle portion 604 with dielectric and prevent both the plasma and inductor coil from interacting with the conductive middle portion 604. For instance, in FIG. 14 an interior of a cylindrical chamber can be seen where a single conductive middle portion 1404 is enclosed by an inner portion 1410 and an outer portion 1412. The detailed view in the upper right corner of FIG. 14 shows how the conductive middle portion 1404 can be formed so as to not reach an end of the inner portion 1410. As a result, when the outer portion 1412 is added to the lamination, it can fill the gap at the end of the conductive middle portion 1404 and thereby enclose it and protect it from plasma.

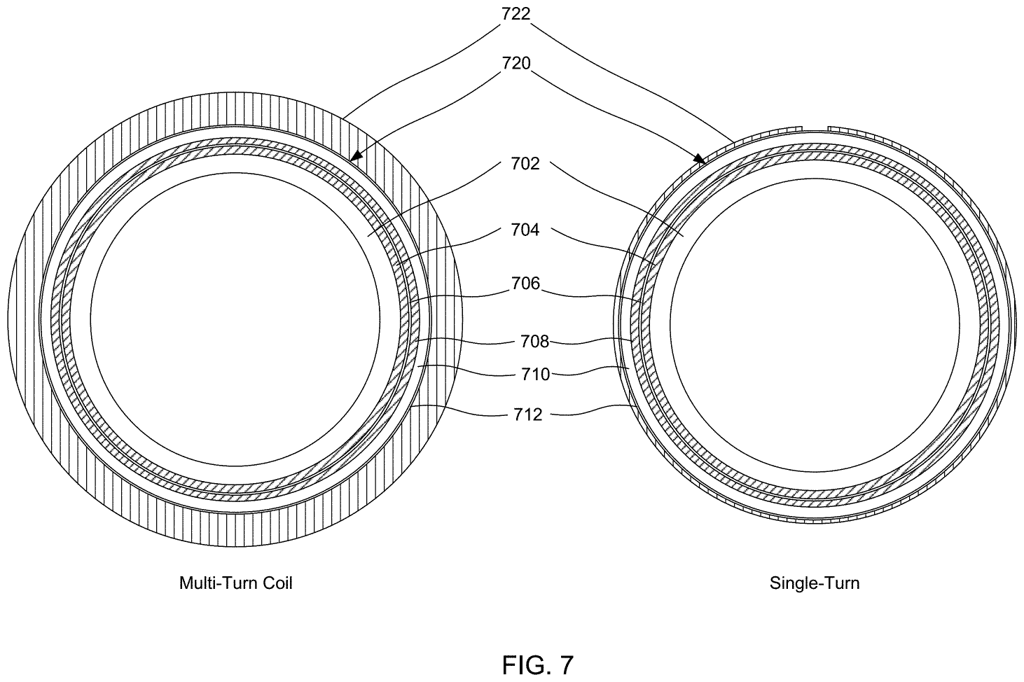

In other embodiments, the conductive middle portion can include two or more layers, each separated by an additional dielectric layer. For instance, FIG. 7 illustrates the cross sections of FIG. 6 but with two conductive layers 704, 708, and a dielectric layer 706 arranged between these. The dielectric layer 706 between each of the two or more conductive layers 704, 708 can be thinner or thicker than the conductive layers 704, 708. In FIG. 7, this layer 706 is thinner than the surrounding conductive layers 704, 708, but in other embodiments this need not be the case.

Like the embodiments of FIG. 6, the cylindrical chamber 720 can include an inner portion 702, an outer portion 710, a thermal transport medium 712, and one or more conductive coils 722. The conductive middle portion comprises two parts: a first conductive layer 704, and a second conductive layer 708. These two conductive layers can be separated by a dielectric layer 706. In an embodiment, the first conductive layer 704, which is closer to the plasma, can be designed to primarily reduce capacitive coupling between the conductive coil(s) 722 and the plasma, while the second conductive layer 708, which is closer to the coil(s) 722 can be designed to primarily transfer heat. For instance, the second conductive layer 708 can be thicker than the first conductive layer 704. The dielectric layer 706 can be thinner than either of the conductive layers 704, 708. The thermal transport medium 712 may be foregone where the single-turn coil 722 is formed from a thin conductive layer formed via an additive process.

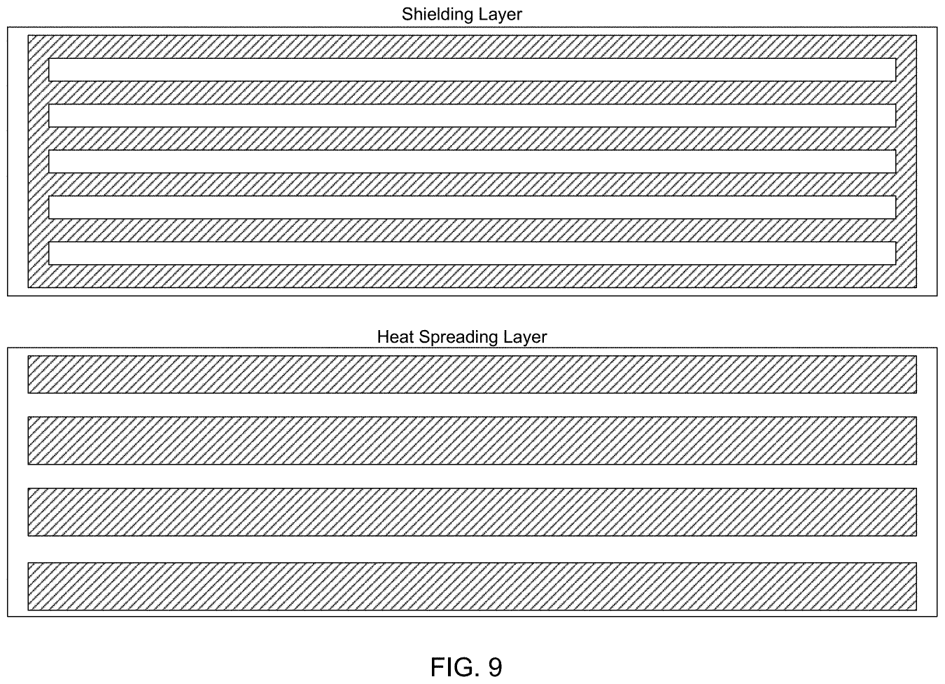

One reason that two or more conductive layers may be desired is where one is used as a Faraday shield, or to mitigate capacitive coupling between the coils and the plasma, while the other conductive layer is configured to enhance thermal transport and reduce thermal gradients. In such a situation, the magnetic-field-passage windows may have distinct designs for the two or more conductive layers. For instance, FIGS. 9-11 show variations of magnetic-field-passage windows that could be implemented on the different conductive layers. Along similar lines, any conductive layer used primarily for thermal transport can be thicker than layers used primarily as Faraday shields.

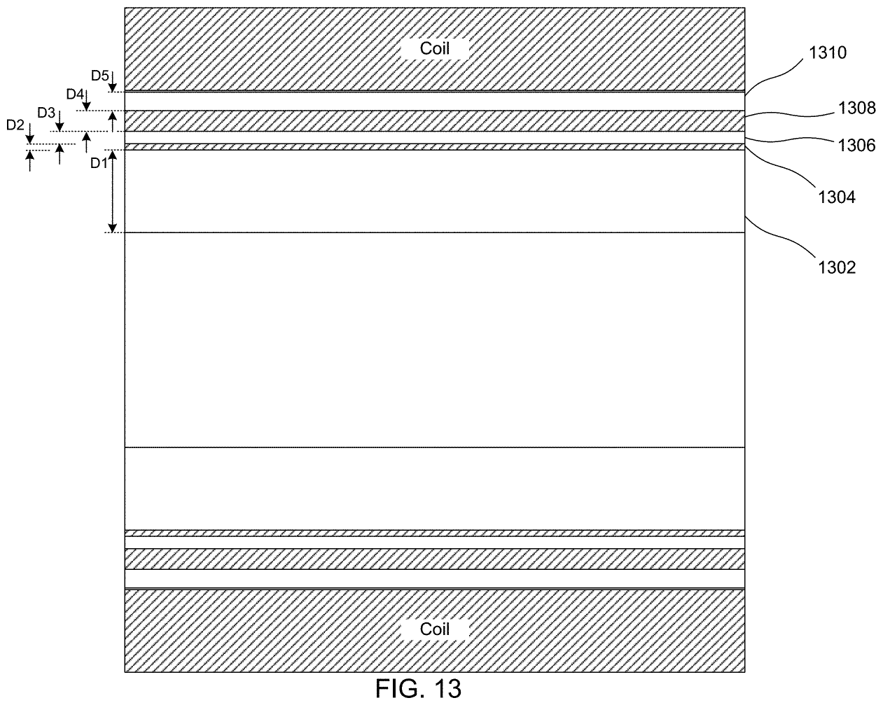

FIG. 13 illustrates a cross section of a remote plasma source having an inner portion 1302, a first conductive layer 1304, a dielectric layer 1306, a second conductive layer 1308, an outer portion 1310, and a single-turn or multi-turn coil in contact with and surrounding the outer portion 1310. Each of these layers or portions has a thickness, denoted D1, D2, D3, D4, or D5. In most embodiments, D1 is greater than all other thicknesses since the additional layers/portions are fabricated via additive processes atop the cylindrical chamber, which acts as a substrate. In an embodiment, D1>D4>D5>D3>D2. In an embodiment, D1>D4 and D1>D5, where D4=D5, and D4>D2. In an embodiment, D1>D4>D5 and D4>D2.

Many of the magnetic-field-passage windows shown in this disclosure are longitudinally arranged. This may be preferred where there is a desire to enhance thermal transport in a longitudinal direction. For instance, since the plasma typically has a greatest density and heat toward a middle of the cylindrical chamber, a large thermal gradient can form from the center toward ends of the cylindrical chamber, and this gradient can degrade the chamber. The disclosed longitudinal windows allow for longitudinal conductive paths, not seen in a non-laminated cylindrical chamber, and therefore enhance thermal transport between a middle and ends of the cylindrical chamber. Although FIG. 13 only shows two conductive layers, and a relatively thicker coil, in some embodiments, greater than two conductive layers may be used, and a thinner coil may be used (e.g., one having a thickness similar to that of one of the conductive layers).

Returning to FIG. 6, the conductive coil 622 can be helical and can have a rectangular cross section or a circular or ovular cross section, e.g., see FIG. 14, among others. For instance, to maximize coil contact with the outer portion 606 and thereby maximize thermal transport to the coil 622, the conductive coil 622 may have a cross section that is relatively flat (or slightly concave) on a bottom side thereby maximizing surface area contact between the conductive coil 622 and the outer portion 606. Said another way, the conductive coil 622 can have a wider cross section measured along a longitudinal dimension/axis of the cylindrical chamber 620 than the cross section measured radially. Although FIG. 14 shows a multi-turn coil having a circular cross section, a rectangular cross section can also be used. While use of a rectangular cross section coil can enhance thermal transport to the coil, shaping an outer surface of the chamber to seat the coil can further enhance transport. For instance, a groove can be formed in an outer surface of the chamber that is the same or slightly larger than the size of the coil, thereby allowing the coil to be partially seated below an outermost surface of the chamber. Where a groove is formed in the chamber wall, the coil may be threaded into the groove rather than expanded and collapsed as is a preferred assembly step when the chamber is not grooved. This disclosure is equally applicable to planar coils and chambers.

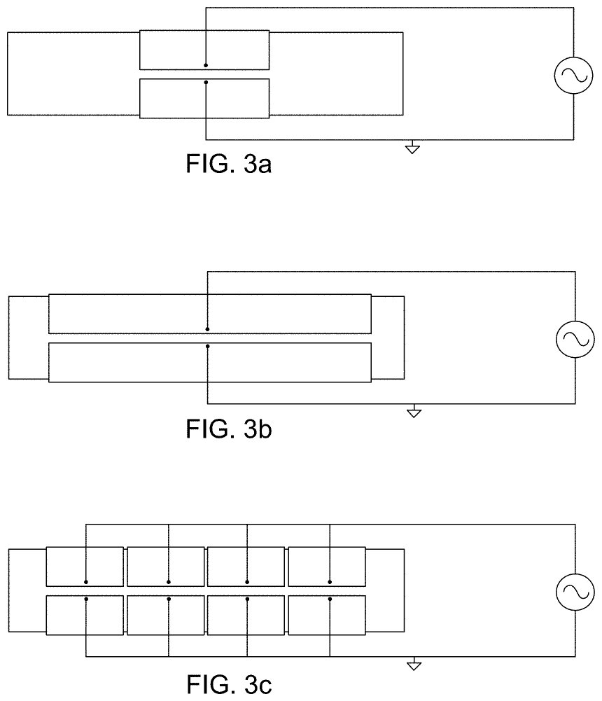

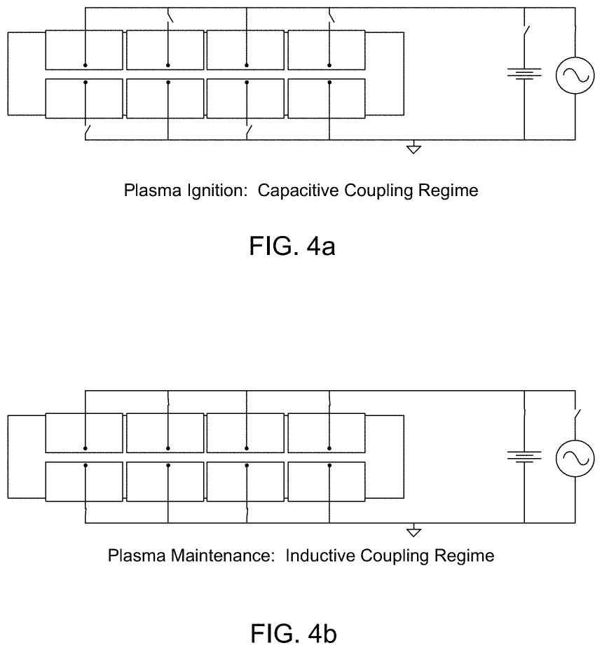

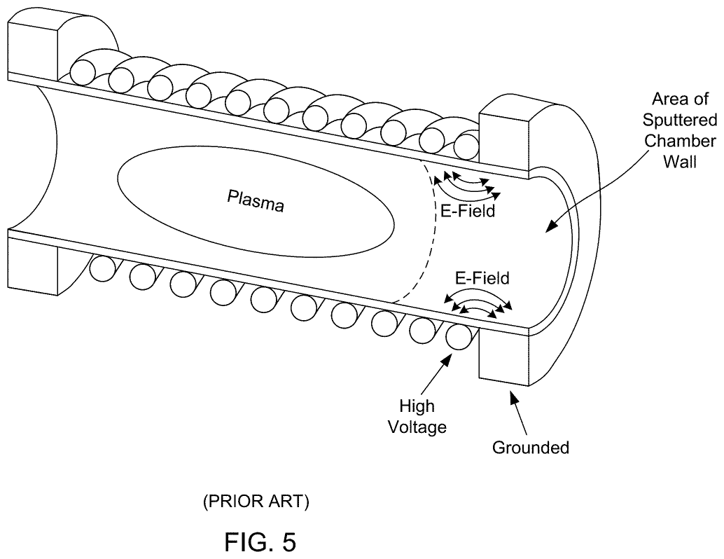

While inductively-coupled plasma sources typically use a multi-turn helical coil, as seen in FIGS. 1b and 2b, each additional turn increases voltage and thus capacitive coupling with the plasma. Therefore, one way to reduce coupling is to implement a single-turn coil as seen for example in FIGS. 1a, 2b, 3, 4, 6 (right figure), and 7 (right figure). With a single-turn coil, the coil can follow a circumferential path around the cylindrical chamber rather than a helical path. Although a single-turn coil has less capacitive coupling with the plasma, it also results in lower inductive coupling for the same voltage and current. Therefore, to achieve the same inductive power transfer to the plasma as a multi-turn coil, the current can be increased in the single-turn coil.

Where a single-turn coil is used, the coil can span any length of the cylindrical chamber, though preferably between 60% and 90% of the length of the cylindrical chamber as shown in FIGS. 3a and 3b. Greater length also leads to greater current-carrying capacity, which may be helpful to achieve adequate power transfer to the plasma. FIGS. 3a-c show different embodiments of a single-turn coil surrounding the cylindrical chamber with FIG. 3c showing a variation where the single-turn coil is split into multiple, identically-biased, portions. FIGS. 3a and 3b show different lengths of the single-turn coil, where the length can be selected to achieve a desired position and/or shape of the plasma. Each of these portions can have the same bias, although in other embodiments, these separate portions can have distinct biases as shown in FIG. 4. For instance, FIG. 4 shows two different states of the same bias circuitry: in FIG. 4a, adjacent single-turn coils are biased as opposing electrodes such that the system capacitively couples to the plasma; in FIG. 4b, each single-turn coil has the same bias and opposing ends of each coil are oppositely biased such that the system inductively couples to the plasma. FIG. 4 is illustrative only, and many other circuit configurations and single-turn coil configurations (e.g., greater or lesser than 4 isolated coils) could be implemented to achieve the same functionality—of switching between a capacitive and an inductive source. The different regions may receive different biases during plasma ignition and then the same bias (or ground potential) during plasma maintenance.

Unless otherwise specified, any of the conductive coils shown in the figures can be either single-turn or multi-turn.

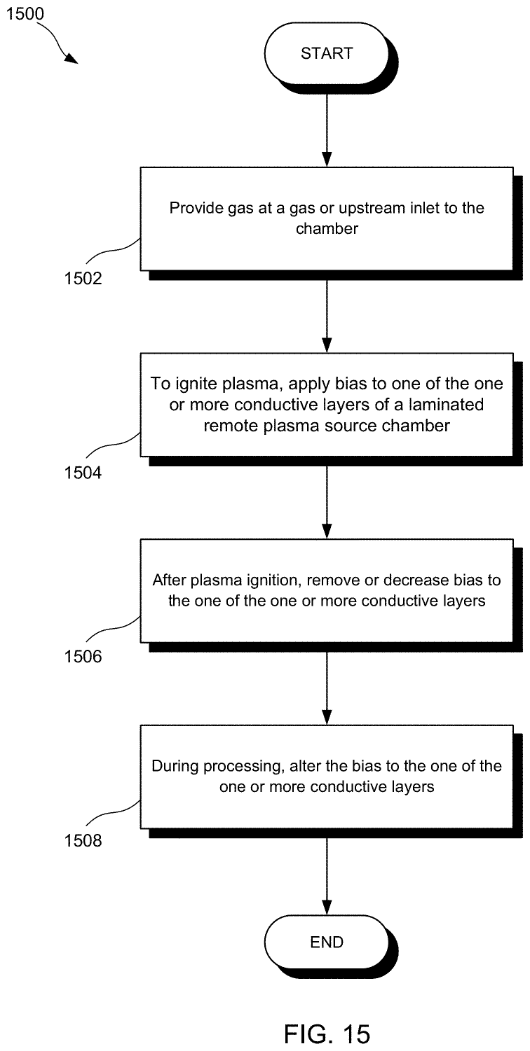

FIG. 15 illustrates a method 1500 of operating a remote plasma source. The herein disclosed remote plasma source can be operated in either an upstream (see FIG. 1) or downstream (see FIG. 2) configuration. In either configuration a gas can be provided at a gas inlet or upstream inlet of the remote plasma source (Block 1502). A bias can be applied to one of one or more conductive layers in the laminated remote plasma source chamber, along with a bias applied to a single or multi-turn coil wrapped around the laminated remote plasma source chamber (Block 1504). These biases generate both inductive and capacitive coupling to the gas in the chamber to ignite a plasma. Once ignited, the bias to the one of the one or more conductive layers can be removed or decreased (Block 1506), thereby reducing capacitive coupling to the ignited plasma, and leaving the conductive layer(s) to operate as partial Faraday shields that reduce capacitive coupling between the coil and the ignited plasma. After plasma ignition, and during plasma processing, the bias on the one of the one or more conductive layers can be altered (e.g., increased) (Block 1508). For instance, the bias may be increased in order to alter the chemistry of the downstream chemistry.

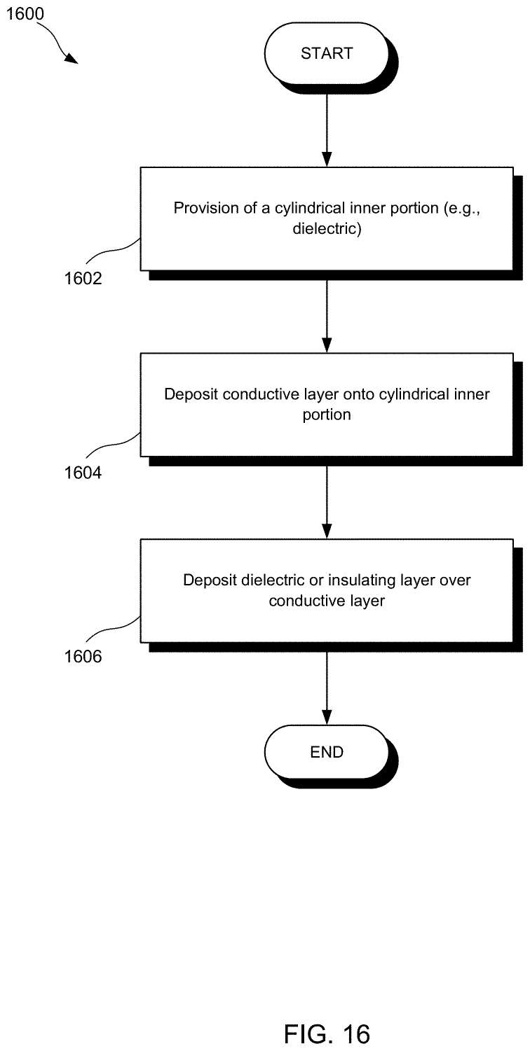

FIG. 16 illustrates a method 1600 of fabricating a laminated remote plasma source chamber with a single or multi-turn coil. The lamination process can start with provision of a cylindrical inner portion formed of, for instance, a dielectric (Block 1602). A conductive layer can then be deposited onto the cylindrical inner portion (Block 1604). The conductive layer can include one or more magnetic-field-passage windows. The windows can be formed by etching the conductive layer or by providing a mask before the conductive layer is added. The addition of the conductive layer can involve any additive process or a fusing of a conductive layer to the underlying inner portion (e.g., via brazing). A dielectric layer can then be deposited over the conductive layer and those portions of the cylindrical inner portion that are exposed through the magnetic-field-passage windows in the conductive layer (Block 1606).

Any of the one or more conductive layers can be formed to be between 10 and 20 μm thick. Where there are at least two conductive layers, a first can be designed as a Faraday shield while the other is designed as a thermal transport layer. These responsibilities may affect the thickness, material, and window shape/size of each layer. For instance, to decrease thermal gradients, a conductive layer can be selected to be thicker than a conductive layer primarily responsible for reducing capacitive coupling. This can be seen, for instance, in FIG. 13 where conductive layer 1308 is thicker than conductive layer 1304.

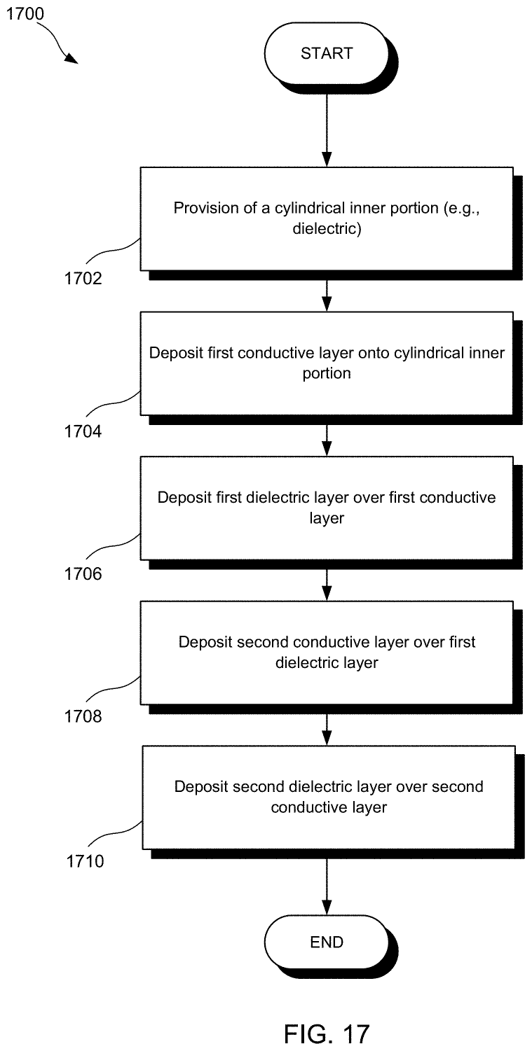

FIG. 17 illustrates a method 1700 of fabricating a laminated remote plasma source with a single or multi-turn coil and at least two conductive layers. The lamination process can start with provision of a cylindrical inner portion formed of, for instance, a dielectric (Block 1702). A first conductive layer can then be deposited onto the cylindrical inner portion (Block 1704). The first conductive layer can include one or more magnetic-field-passage windows. The windows can be formed by etching the conductive layer or by providing a mask before the conductive layer is added. The addition of the conductive layer can involve any additive process or a fusing of a conductive layer to the underlying inner portion (e.g., via brazing). A first dielectric layer can then be deposited over the conductive layer and those portions of the cylindrical inner portion that are exposed through the magnetic-field-passage windows in the conductive layer (Block 1706). A second conductive layer can be deposited onto an outer surface of the first dielectric layer (Block 1708), where this layer may also include one or more magnetic-field-passage windows exposing the first dielectric layer through the windows in the second conductive layer (see also FIGS. 7, 9, 10, 11, and 13). A second dielectric layer can then be deposited over the second conductive layer and those portions of the first dielectric layer exposed through the windows in the second conductive layer (Block 1710). This final dielectric layer encloses and protects the conductive layer from the plasma as well as provides a dielectric barrier between the second conductive layer and the coil. Further steps could be implemented to add additional conductive and dielectric layers.

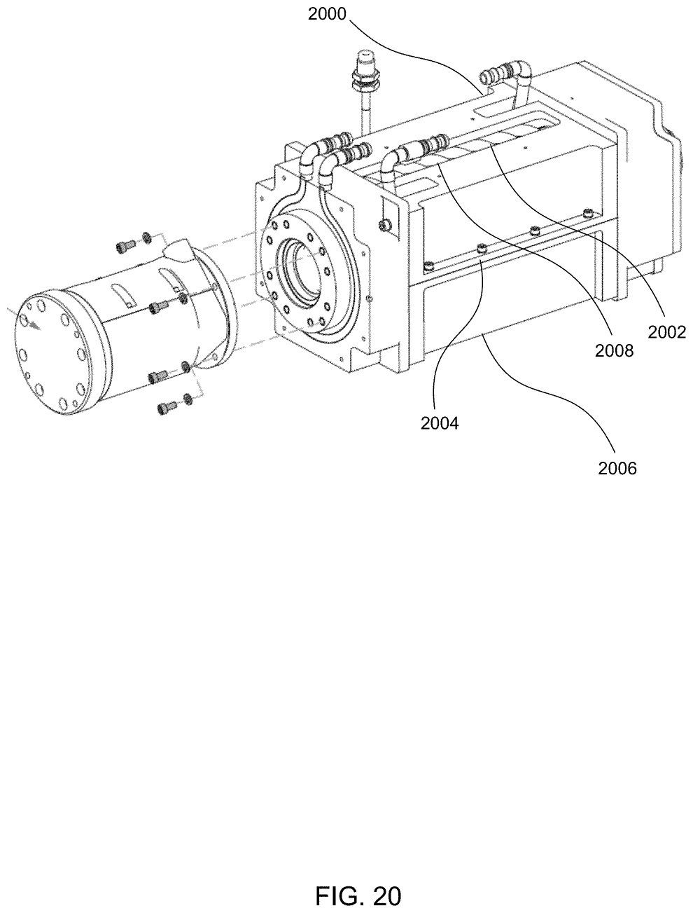

FIG. 18 illustrates a method 1800 of applying a curable thermal transport medium to a laminated remote plasma source chamber with either a single or multi-turn coil. The coil can be installed over the cylindrical laminated chamber (Block 1802). For instance, the coil can be expanded, arranged around the chamber, and released so that the coil tightens against the outer wall of the cylindrical chamber. Alternatively, a single-turn coil can be fused to the cylindrical chamber or coated on the cylindrical chamber with an additive process. A housing can then be formed around the cylindrical chamber and coil (Block 1804). This housing can be formed from multiple components and once installed the housing forms an enclosure, for instance enclosing the chamber and coils on all sides, save a pour opening near a top of the enclosure (e.g., see FIG. 20). The housing can be sealed off from an inside of the chamber wall, to prevent the thermal transport medium from coming into contact with the inside of the chamber. “Chimney” tubes can optionally be installed in the housing that will help pull air out of the housing when it is being filled with thermal-transport medium (Block 1806). The thermal-transport medium can then be formed (e.g., by mixing a potting compound) (Block 1808), and this can be poured through the pour opening and into the housing (Block 1810). The thermal-transport medium, in fluid form, can encase the coil and cylindrical chamber, or encase at least 60% of a surface of the coil. In an embodiment, the thermal-transport medium can be a 2-part silicone-based elastomer with ceramic particles suspended therein to enhance thermal conductivity. The housing can then be placed into a vacuum chamber to de-gas the thermal-transport medium and remove air bubbles (Block 1812). The housing can then optionally be heated to cure the thermal-transport medium (Block 1814). For instance, the assembly can be placed in an oven for 30 minutes at 70° and then 50 minutes at 100°. Once curing is complete, the housing and chimney tubes can be removed (Block 1816).

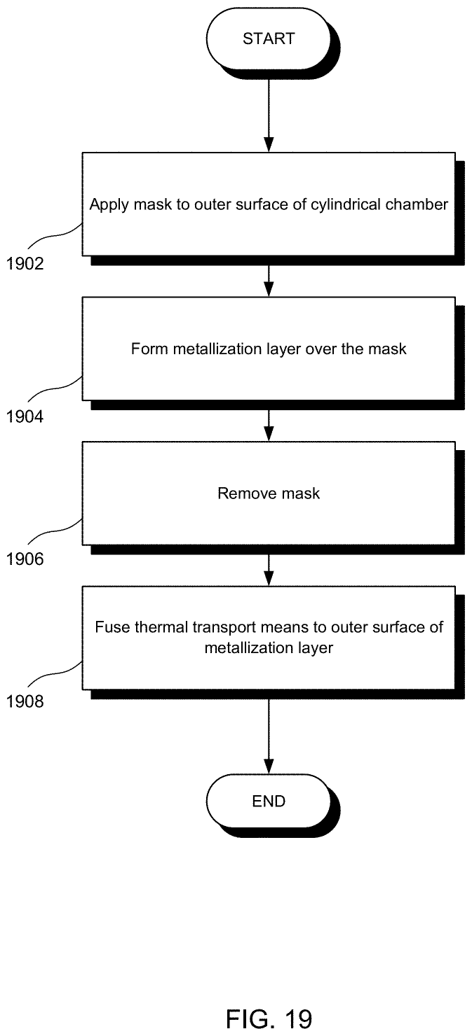

FIG. 19 illustrates another method of fabricating a remote plasma source chamber with a single-turn coil formed via an additive process. Assembly can begin with a cylindrical chamber (optionally laminated according to the methods 1600 or 1700). A mask or screen can be applied to an outer surface of the cylindrical chamber (Block 1902). The mask or screen can define a gap between two ends of the to-be-generated single-turn thin conductive coil. A metallization layer can be formed over the mask or screen (Block 1904), where the metallization layer bonds to those portions of the cylindrical chamber exposed through the mask. The metallization layer can use any additive process (e.g. thermal or plasma assisted metallization) or fusing process (e.g., brazing). The metallization layer can be formed from refractory inks (e.g. Cu, Ag, Mo—Mn), plating (e.g. Ni), vacuum or plasma-assisted coating (Au—Pd, Cu, Cu—Ni), or brazing of a thin, pre-formed conductor, and can be between 10 and 200 μm thick. The mask and that portion of the metallization layer bonded to the mask can be removed (Block 1906). A thermal transport means, such as a cooling fluid pipe (air or liquid) or fluid jacket can be fused to an outer surface of the metallization layer (Block 1908). The gap in the metallization layer can leave two ends to a single-turn coil and connections to the two ends can be formed as one or more brazed or soldered power tap blocks, electrically conductive gaskets or springs, or flexible straps, to name just a few non-limiting examples. Where a screen, rather than a mask, is used, the screen can be removed after a metal paste is applied, but prior to firing/solidifying the metal paste.

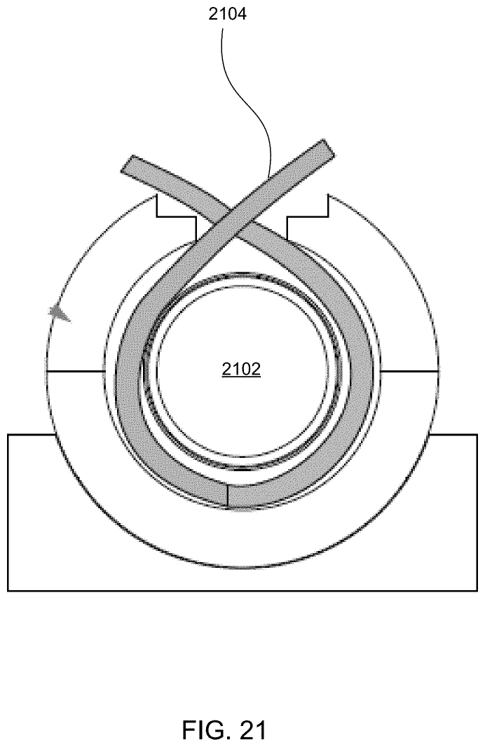

FIG. 20 illustrates a housing into which a remote plasma source can be placed in preparation for pouring of a thermal transport medium. The housing 2000 can include a first portion 2004 and a second portion 2006 that can be arranged to enclose the remote plasma source 2002 in a clamshell fashion. The housing 2000 may include a pour opening 2008, and an optional pour spout (not shown) can be secured to or through the pour opening 2008. Further, optional chimney tubes (see 2104 in FIG. 21) can be inserted through the pour opening 2008 and can be made to pass under and around the remote plasma source 2102. A thermal transport medium can then be poured through the pour opening 2008 to fill the housing and all gaps between the single or multi-turn coil and the cylindrical chamber of the remote plasma source 2002. The housing 2000 and the thermal transport medium can be heated so as to cure the thermal transport medium, and then the housing 2000 can then be removed.

In some embodiments, the thermal transport medium can be formed silicone based (e.g., Polydimethylsiloxane) and filled with Al₂O₃ or ZnO. The filler can comprise between 50 and 85% of the thermal transport medium by weight. In one embodiment, the filler can comprise greater than 25% by weight of the thermal transport medium.

Although this disclosure has described a single-turn coil surrounding a traditional and laminated chamber wall, in other embodiments a double-turn or triple-turn coil could be used. Typical inductively coupled sources utilize plentiful turns to generate sufficient fields to ignite and maintain the plasma. As previously noted, the numerous coils lead to unwanted capacitive coupling between the coils and other portions of the system. Reducing the number of coils to a single turn, or even two or three turns in some cases, can drastically reduce this capacitive coupling while still providing sufficient inductive coupling to maintain the plasma within the remote source. However, embodiments where only one to three turns are used may suffer from a degraded ability to ignite plasma. Therefore, a temporary high voltage may be applied to the coil or to a conductive layer within the laminated chamber wall, or to both, to ignite the plasma, followed by a voltage reduction to a plasma maintenance level below the ignition level. In this way, a single, double, or triple-turn coil can operate in both an ignition regime (capacitive coupling) for a short period followed by a much longer maintenance regime (inductive coupling).

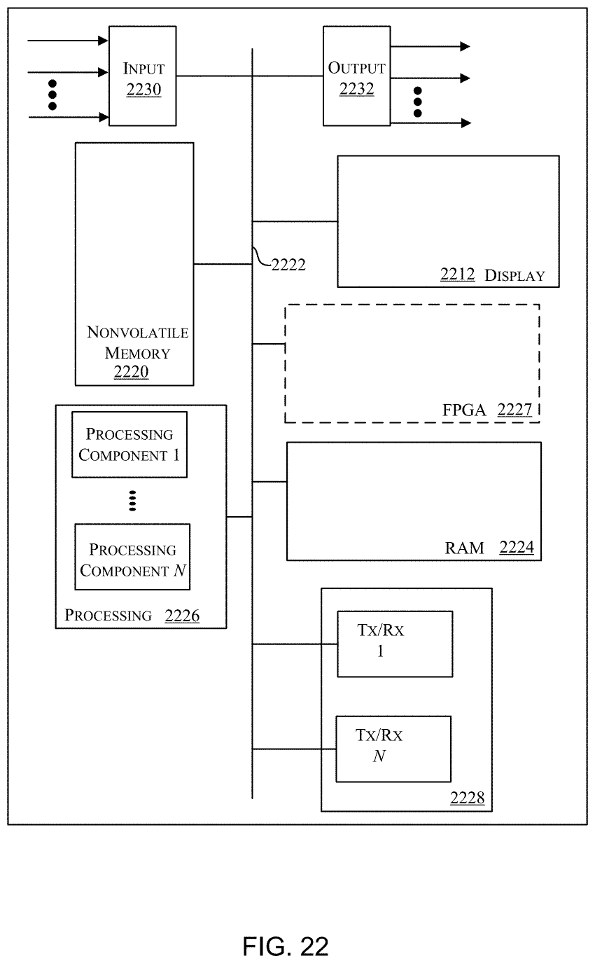

The methods described in connection with the embodiments disclosed herein may be embodied directly in hardware, in processor-executable code encoded in a non-transitory tangible processor readable storage medium, or in a combination of the two. Referring to FIG. 22 for example, shown is a block diagram depicting physical components that may be utilized to realize a device for operating or manufacturing the remote plasma sources herein disclosed according to an exemplary embodiment. As shown, in this embodiment a display portion 2212 and nonvolatile memory 2220 are coupled to a bus 2222 that is also coupled to random access memory (“RAM”) 2224, a processing portion (which includes N processing components) 2226, an optional field programmable gate array (FPGA) 2227, and a transceiver component 2228 that includes N transceivers. Although the components depicted in FIG. 22 represent physical components, FIG. 22 is not intended to be a detailed hardware diagram; thus many of the components depicted in FIG. 22 may be realized by common constructs or distributed among additional physical components. Moreover, it is contemplated that other existing and yet-to-be developed physical components and architectures may be utilized to implement the functional components described with reference to FIG. 22.

This display portion 2212 generally operates to provide a user interface for a user, and in several implementations, the display is realized by a touchscreen display. In general, the nonvolatile memory 2220 is non-transitory memory that functions to store (e.g., persistently store) data and processor-executable code (including executable code that is associated with effectuating the methods described herein). In some embodiments for example, the nonvolatile memory 2220 includes bootloader code, operating system code, file system code, and non-transitory processor-executable code to facilitate the execution of methods described with reference to FIGS. 15-19 described further herein.

In many implementations, the nonvolatile memory 2220 is realized by flash memory (e.g., NAND or ONENAND memory), but it is contemplated that other memory types may be utilized as well. Although it may be possible to execute the code from the nonvolatile memory 2220, the executable code in the nonvolatile memory is typically loaded into RAM 2224 and executed by one or more of the N processing components in the processing portion 2226.

The N processing components in connection with RAM 2224 generally operate to execute the instructions stored in nonvolatile memory 2220 to enable the methods of FIGS. 15-19. For example, non-transitory, processor-executable code to effectuate the methods described with reference to FIGS. 15-19 may be persistently stored in nonvolatile memory 2220 and executed by the N processing components in connection with RAM 2224. As one of ordinarily skill in the art will appreciate, the processing portion 2226 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, the processing portion 2226 may be configured to effectuate one or more aspects of the methodologies described herein (e.g., the methods described with reference to FIGS. 15-19). For example, non-transitory processor-readable instructions may be stored in the nonvolatile memory 2220 or in RAM 2224 and when executed on the processing portion 2226, cause the processing portion 2226 to perform the methods of FIGS. 15-19. Alternatively, non-transitory FPGA-configuration-instructions may be persistently stored in nonvolatile memory 2220 and accessed by the processing portion 2226 (e.g., during boot up) to configure the hardware-configurable portions of the processing portion 2226 to effectuate the methods of FIGS. 15-19.

The input component 2230 operates to receive signals (e.g., feedback regarding successful ignition of a plasma to trigger a change from capacitive coupling to a shielding regime of the conductive layer(s)). The signals received at the input component may include, for example, an indication that deposition of a conductive layer should cease.

The depicted transceiver component 2228 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

Some portions are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

As used herein, the recitation of “at least one of A, B and C” is intended to mean “either A, B, C or any combination of A, B and C.” The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A remote plasma source chamber with extended lifetime configured for coupling to a processing chamber, the remote plasma source chamber comprising:
a cylindrical chamber having:
an inner portion comprising a first dielectric;
an outer portion comprising a second dielectric;
a conductive middle portion between the inner and outer portion defining one or more magnetic-field-passage windows;
a conductive coil arranged outside but in contact with the cylindrical chamber, the conductive coil comprising a plurality of separate coil portions, each coil portion including a first end and a second end, the first end configured for coupling to a high voltage node of an alternating current power supply, the second end configured for coupling to a low voltage or ground node of the alternating current power supply; and
bias circuitry configured to switch between biasing adjacent coil portions with different biases and biasing each coil portion with a same bias.

2. The remote plasma source chamber of claim 1, wherein the bias circuitry is configured to, in a first state, bias adjacent coil portions as opposing electrodes using different biases.

3. The remote plasma source chamber of claim 2, wherein the conductive coil is configured to be a capacitive source while the bias circuitry is in the first state.

4. The remote plasma source chamber of claim 1, wherein the bias circuitry is configured to bias adjacent coil portions with different biases during plasma ignition.

5. The remote plasma source chamber of claim 2, wherein the bias circuitry is configured to, in a second state, bias adjacent coil portions with the same bias.

6. The remote plasma source chamber of claim 5, wherein the conductive coil is configured to be an inductive source while the bias circuitry is in the second state.

7. The remote plasma source chamber of claim 1, wherein the bias circuitry is configured to bias each coil portion with the same bias during plasma maintenance.

8. A remote plasma source chamber with extended lifetime configured for coupling to a processing chamber, the remote plasma source chamber comprising:
a cylindrical chamber having:
an inner portion comprising a first dielectric;
an outer portion comprising a second dielectric;
a conductive middle portion between the inner and outer portion defining one or more magnetic-field-passage windows, wherein the one or more magnetic-field-passage windows are elongated along a longitudinal axis of the cylindrical chamber;
a conductive coil arranged outside but in contact with the cylindrical chamber, the conductive coil comprising a plurality of separate coil portions, each coil portion including a first end and a second end, the first end configured for coupling to a high voltage node of an alternating current power supply, the second end configured for coupling to a low voltage or ground node of the alternating current power supply, wherein the conductive coil makes a single turn around the cylindrical chamber; and
bias circuitry configured to switch between biasing adjacent coil portions with different biases and biasing each coil portion with a same bias.

9. The remote plasma source chamber of claim 8, wherein the conductive coil follows a circumferential path around the cylindrical chamber rather than a helical path.

10. The remote plasma source chamber of claim 8, wherein the bias circuitry is configured to, in a first state, bias adjacent coil portions as opposing electrodes using different biases.

11. The remote plasma source chamber of claim 10, wherein the conductive coil is configured to be a capacitive source while the bias circuitry is in the first state.

12. The remote plasma source chamber of claim 8, wherein the bias circuitry is configured to bias adjacent coil portions with different biases during plasma ignition.

13. The remote plasma source chamber of claim 10, wherein the bias circuitry is configured to, in a second state, bias adjacent coil portions with the same bias.

14. The remote plasma source chamber of claim 13, wherein the conductive coil is configured to be an inductive source while the bias circuitry is in the second state.

15. The remote plasma source chamber of claim 8, wherein the bias circuitry is configured to bias each coil portion with the same bias during plasma maintenance.

16. A remote plasma source chamber with extended lifetime configured for coupling to a processing chamber, the remote plasma source chamber comprising:
a cylindrical chamber having:
an inner portion comprising a first dielectric that is electrically insulating and thermally conductive;
an outer portion comprising a second dielectric that is electrically insulating and thermally conductive;
a conductive middle portion between the inner and outer portion defining one or more magnetic-field-passage windows, wherein the one or more magnetic-field-passage windows are elongated along a longitudinal axis of the cylindrical chamber;
a conductive coil arranged outside but in contact with the cylindrical chamber, the conductive coil comprising a plurality of separate coil portions, each coil portion including a first end and a second end, the first end configured for coupling to a high voltage node of an alternating current power supply, the second end configured for coupling to a low voltage or ground node of the alternating current power supply, wherein the conductive coil makes a single turn around the cylindrical chamber and the conductive coil follows a circumferential path around the cylindrical chamber; and
bias circuitry configured to switch between biasing adjacent coil portions with different biases and biasing each coil portion with a same bias.

17. The remote plasma source chamber of claim 16, wherein the bias circuitry is configured to, in a first state, bias adjacent coil portions as opposing electrodes using different biases.

18. The remote plasma source chamber of claim 17, wherein the conductive coil is configured to be a capacitive source while the bias circuitry is in the first state.

19. The remote plasma source chamber of claim 17, wherein the bias circuitry is configured to, in a second state, bias adjacent coil portions with the same bias.

20. The remote plasma source chamber of claim 19, wherein the conductive coil is configured to be an inductive source while the bias circuitry is in the second state.
